(19) United States
(12) Patent Application Publication
(10) Pub. No.: US 2015/0230370 A1
(43) Pub. Date: Aug. 13, 2015

(54) METHOD FOR ADJUSTING CIRCUIT BOARD

(71) Applicant: HON-HAI PRECISION INDUSTRY CO., LTD., New Taipei (TW)

(72) Inventor: CHIH-CHEN LAI, New Taipei (TW)

(21) Appl. No.: 14/609,642

(22) Filed: Jan. 30, 2015

(30) Foreign Application Priority Data
Feb. 12, 2014 (TW) 103104540

(51) Int. Cl. H05K 13/08; H05K 13/00; H05K 13/04

(52) U.S. Cl. CPC H05K 13/08; H05K 13/04; H05K 13/0023

(57) ABSTRACT

A method for adjusting a circuit board includes: providing a dispensing machine including a carrier and a glue dispensing head, a detecting module including a resistance meter and a coordinate recorder, and the circuit board including at least three through conductive vias, each conductive via including a first end surface and a second end surface; putting the circuit board on the carrier and making the first end surfaces contacting the carrier; driving the glue dispensing head to move towards the second end surfaces and recording positions of the glue dispensing head as positions of the second end surfaces when values reading from the resistance meter are no more than a predetermined value; and adjusting the carrier to make all of the second end surfaces locate at a same height according to the positions of the second end surfaces.

### FIELD

The subject matter herein generally relates to assembly technology, particularly to assembly technology for assembling a photoelectric converter module.

### BACKGROUND

A photoelectric converter module usually includes a circuit board, a light emitting/receiving unit mounted on the circuit board, and an optical coupler. A loading surface of the circuit board must be horizontally located at a predetermined height for the light emitting/receiving unit and the optical coupler to be precisely mounted on the loading surface.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a flowchart illustrating a method for adjusting a circuit board according to an exemplary embodiment.

FIG. 2 is an isometric view showing the method of FIG. 1, the method employing a dispensing machine and a detecting module.

FIG. 3 is a block diagram of the detecting module of FIG. 2.

FIG. 4 is an isometric view of the circuit board of FIG. 2.

FIG. 5 is similar to FIG. 4, but viewed from a different angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

The present disclosure is described in relation to a method for adjusting a circuit board.

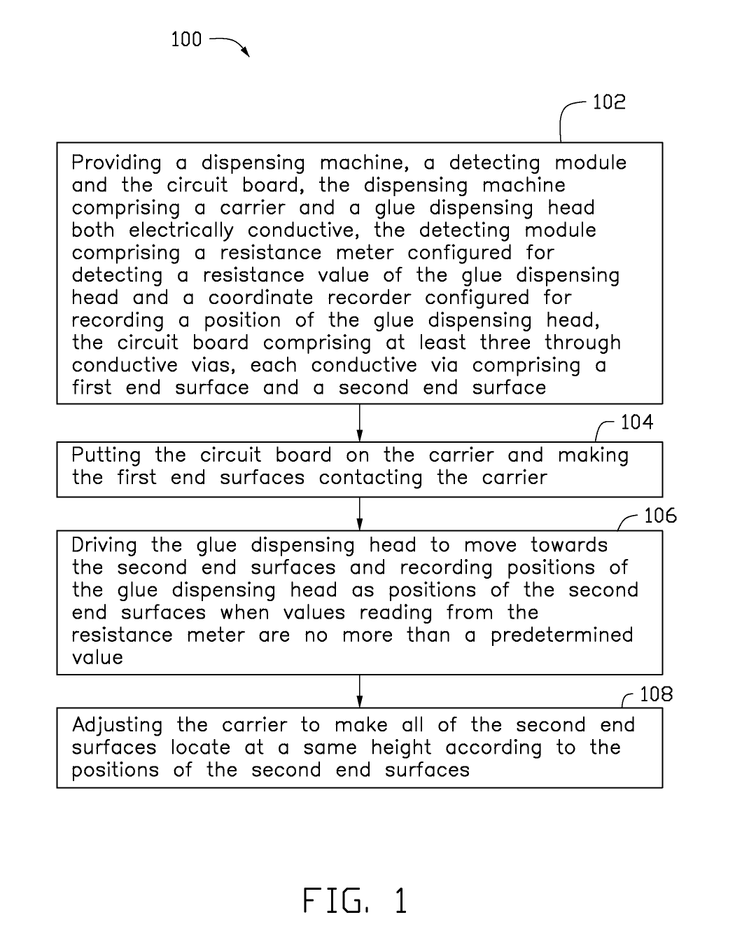

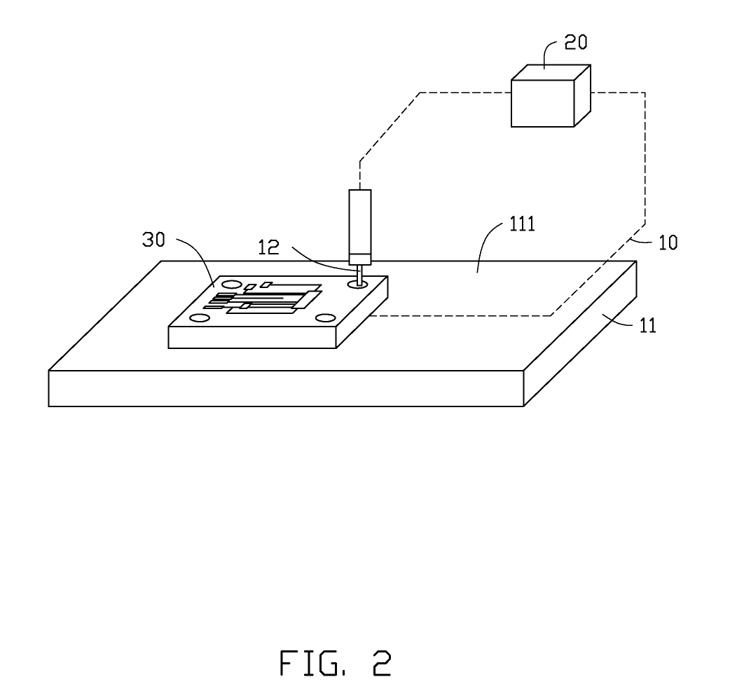

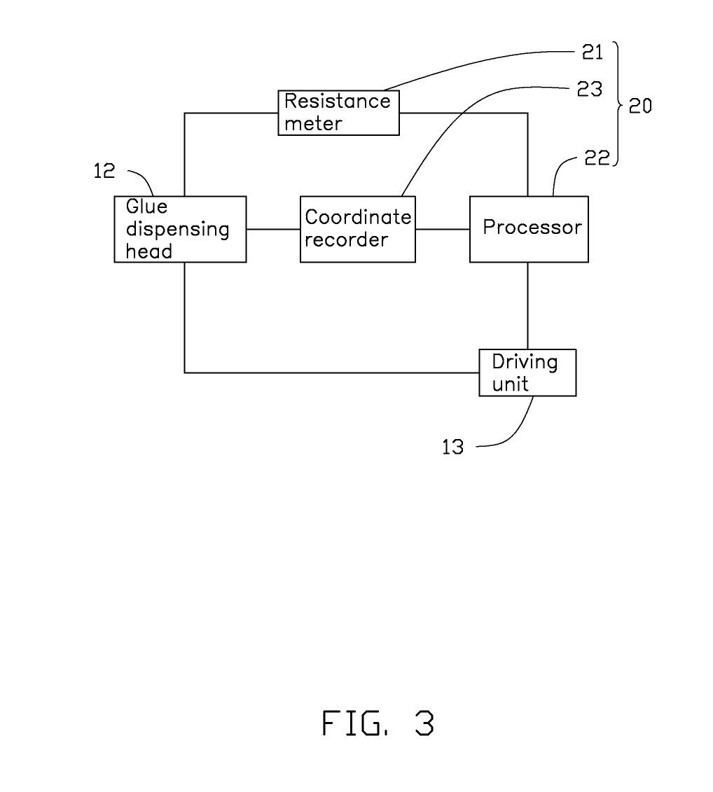

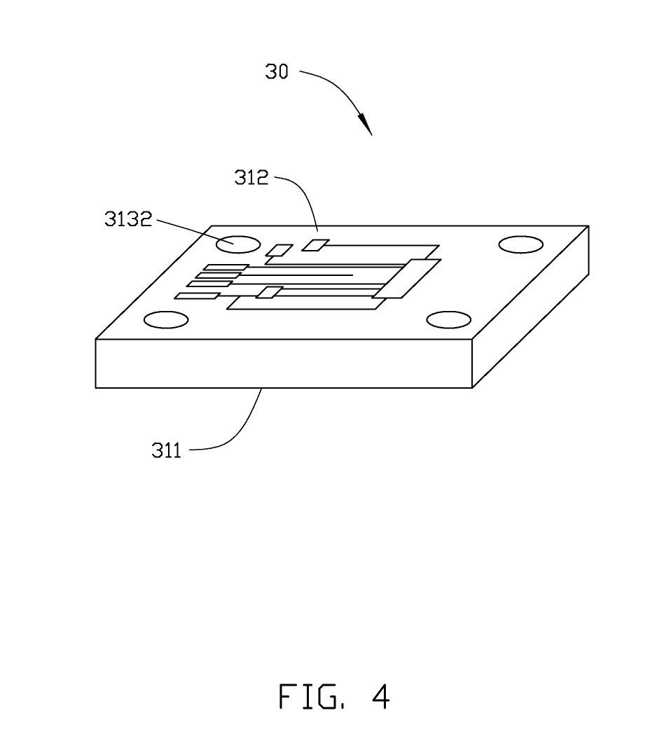

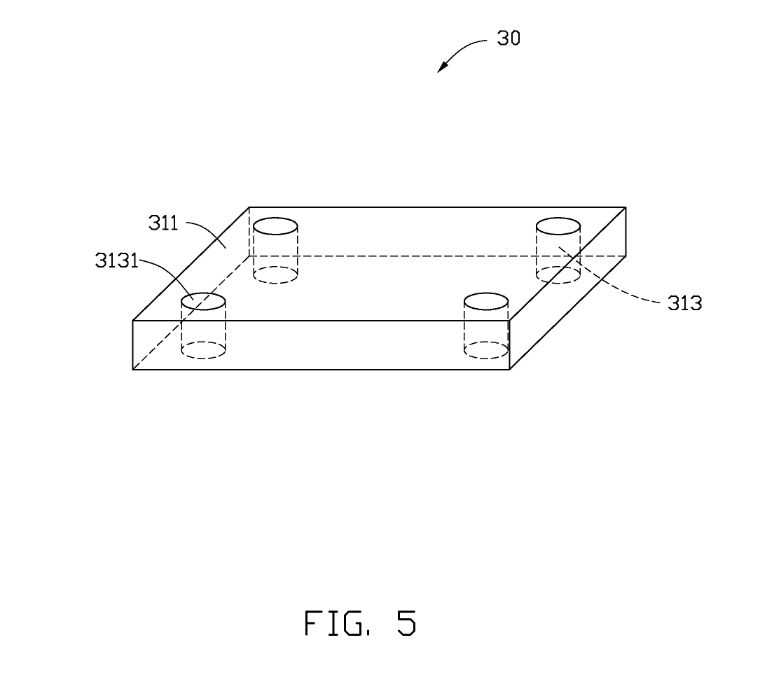

Referring to FIG. 1, a flowchart is presented in accordance with an example embodiment which is being thus illustrated. The method 100 is provided by way of example, as there are a variety of ways to carry out the method. The method 100 described below can be carried out using the configurations illustrated in FIGS. 2 to 5, for example, and various elements of these figures are referenced in explaining example method 100. Each block shown in FIG. 1 represents one or more processes, methods or subroutines, carried out in the exemplary method 100. Additionally, the illustrated order of blocks is by example only and the order of the blocks can change according to the present disclosure. The exemplary method 100 can begin at block 102.

At block 102, a dispensing machine 10, a detecting module 20 and a circuit board 30 are provided. The dispensing machine 10 includes a carrier 11, and a glue dispensing head 12 fixed on a driving unit 13. The carrier 11 is electrically conductive and is grounded. The carrier 11 includes a carrying surface 111. The carrying surface 111 is an even surface. The glue dispensing head 12 is electrically conductive. The driving unit 13 is configured for driving the glue dispensing head 12 or the carrier 11 to move.

The detecting module 20 includes a resistance meter 21 electrically connected to the glue dispensing head 12, a processor 22, and a coordinate recorder 23. The processor 22 is connected to the driving unit 13, the coordinate recorder 23, and the resistance meter 21, and is configured to control the driving unit 13. The resistance meter 21 is used to detect a resistance value of the glue dispensing head 12. The coordinate recorder 23 is used to record a position of the glue dispensing head 12 in a xyz coordinate system.

The circuit board 30 includes a first surface 311 and a loading surface 312 opposite to the first surface 311. The circuit board 30 includes at least three conductive vias 313 extending through the first surface 311 and the carrying surface 312. The vias 313 are filled with electrically conductive material. Each via 313 includes a first end surface 3131 formed on the first surface 311 and a second end surface 3132 formed on the loading surface 312. A size of the second end surface 3132 is bigger than that of the glue dispensing head 12.

At block 104, the circuit board 30 is put on the carrier 11. The first surface 311 and the first end surface 3131 contact the carrying surface 111.

At block 106, the glue dispensing head 12 is driven to contact with the conductive vias 313 respectively and the coordinate recorder 23 records the position of the second end surfaces 3132.

For example, the glue dispensing head 12 moves towards one of the conductive vias 313 till a value read from the resistance meter 21 is no more than a predetermined value, such as, substantially zero. Then the coordinate recorder 23 records a first position of the glue dispensing head 12.

When the glue dispensing head 12 does not contact with the second end surface 3132, the glue dispensing head 12 does not ground, and a value detected by the resistance meter 21 should be substantially infinite and be greater than the predetermined value. When the glue dispensing head 12 contacts with the second end surface 3132, the glue dispensing head 12 is grounded, and a value detected by the resistance meter 21 should be no more than the predetermined value. At this time, the position of the glue dispensing head 12 should be equal to the position of the second end surface 3132. Thus, the first position recorded by the coordinate recorder 23 should be the position of the second end surface 3132. In this way, the position of the second end surface 3132 is detected.

At block 108, the carrier 11 moves all the second end surfaces 3132 to a predetermined height.

As the position of each second end surface 3132 is known, then the carrier 11 can move to adjust the height of each second end surface 3132 till they are located at a predetermined height. All the second end surfaces 3132 are at the predetermined height, thus, the loading surface 312 is at the predetermined height and is parallel to a horizontal plane. Then the glue dispensing head 12 can dispense glue on the loading surface 312 for mounting a light emitting/receiving unit and an optical coupler.

It will be understood that the above particular embodiments are shown and described by way of illustration only. The principles and the features of the present disclosure can be employed in various and numerous embodiments thereof without departing from the scope of the disclosure. The above-described embodiments illustrate the scope of the disclosure but do not restrict the scope of the disclosure.

What is claimed is:

1. A method for adjusting a photoelectric converter module circuit board having at least three conductive areas extending through the circuit board from a first circuit board surface to a circuit board loading surface, the method comprising:
providing:
a dispensing machine with an electrically conductive carrier and an electrically conductive glue dispensing head; and
a detecting module having a resistance meter configured for detecting a resistance value of the glue dispensing head and a coordinate recorder configured for recording a position of the glue dispensing head;
positioning the first circuit board surface on the carrier so that the first surface portion of the at least three conductive areas contact the carrier;
moving the glue dispensing head towards the loading surface portion of the at least three conductive areas;
comparing the output of the resistance meter to a predetermined value;
recording the position of the glue dispensing head as the loading surface portion of the at least three conductive areas when the resistance meter output reaching the predetermined value; and
adjusting the carrier to make the loading surface portion of the at least three conductive areas co-planar.

2. The method of claim 1, wherein the carrier is ground.

3. The method of claim 1, wherein the carrier comprises an even carrying surface for carrying the circuit board.

4. The method of claim 1, wherein the dispensing machine further comprises a driving unit configured for driving the glue dispensing head or the carrier to move.

5. The method of claim 1, wherein the circuit board further comprises a first surface and a loading surface opposite to the first surface, the conductive vias extend through the loading surface and the first surface, the first end surface is formed on the first surface and the second end surface is formed on the loading surface.

6. The method of claim 1, wherein the conductive vias are filled with electrically conductive material.

7. The method of claim 1, wherein a size of the second end surface is bigger than that of the glue dispensing head.
